(19) United States
(12) Patent Application Publication
(10) Pub. No.: US 2024/0266258 A1
(43) Pub. Date: Aug. 8, 2024

(54) SEMICONDUCTOR DEVICE

(71) Applicant: ROHM CO., LTD., Kyoto-shi (JP)

(72) Inventor: Kentaro CHIKAMATSU, Kyoto-shi (JP)

(73) Assignee: ROHM CO., LTD., Kyoto-shi (JP)

(21) Appl. No.: 18/636,274

(22) Filed: Apr. 16, 2024

Related U.S. Application Data
(63) Continuation of application No. PCT/JP2022/035311, filed on Sep. 22, 2022.

(30) Foreign Application Priority Data
Nov. 9, 2021 (JP) 2021-182549

(51) Int. Cl. H01L 23/482; H01L 29/20; H01L 29/40; H01L 29/778

(52) U.S. Cl. CPC H01L 23/4824; H01L 29/2003; H01L 29/402; H01L 29/7786

(57) ABSTRACT

A semiconductor device is provided with: a source wiring electrically coupled to the source electrode of a transistor; a drain wiring electrically coupled to the drain electrode of the transistor; a source pad electrically coupled to the source wiring; and, a drain pad electrically coupled to the drain wiring. The source wiring includes a first source wiring section and a second source wiring section having a width greater than that of the first source wiring section. The drain wiring includes a first drain wiring section and a second drain wiring section having a width greater than that of the first drain wiring section. The source pad at least partially overlaps the second drain wiring section in plan view. The drain pad at least partially overlaps the second source wiring section in plan view.

### CROSS-REFERENCE TO RELATED APPLICATIONS

The present application is a bypass continuation of International Patent Application No. PCT/JP2022/035311, filed on Sep. 22, 2022, which claims priority to Japanese Patent Application No. 2021-182549 filed in the Japan Patent Office on Nov. 9, 2021, the entire disclosures of these applications are incorporated herein by reference.

### BACKGROUND

### 1. Field

The present disclosure relates to a semiconductor device.

### 2. Description of Related Art

Japanese Laid-Open Patent Publication No. 2020-202310 discloses a multilayer interconnect structure of a semiconductor device. The multilayer interconnect structure disclosed in Japanese Laid-Open Patent Publication No. 2020-202310 includes an interconnect metal structure, an interlayer insulation film formed on the interconnect metal structure, and a pad structure formed on the interlayer insulation film. The interconnect metal structure includes source interconnect metals and drain interconnect metals extending in an X-direction. The source interconnect metals and the drain interconnect metals are alternately arranged in a Y-direction. The pad structure includes a source pad and a drain pad extending the Y-direction. Source vias extend through the interlayer insulation film to electrically connect the source pad to source interconnect metals that are orthogonal to the source pad. Drain vias extend through the interlayer insulation film to electrically connect the drain pad to drain interconnect metals that are orthogonal to the drain pad.

### BRIEF DESCRIPTION OF THE DRAWINGS

FIG. 1 is a schematic plan view showing an exemplary semiconductor device in an embodiment.

FIG. 2 is an enlarged plan view showing region F2 of the semiconductor device shown in FIG. 1.

FIG. 3 is a schematic cross-sectional view of the semiconductor device taken along line F3-F3 in FIG. 2.

FIG. 4 is a schematic cross-sectional view showing an example of a transistor.

FIG. 5 is a schematic plan view showing a comparative example of a semiconductor device.

FIG. 6 is an enlarged plan view showing region F6 of the semiconductor device shown in FIG. 5.

FIG. 7 is an enlarged plan view showing a first modified example of a semiconductor device.

FIG. 8 is an enlarged plan view showing a second modified example of a semiconductor device.

FIG. 9 is an enlarged plan view showing a third modified example of a semiconductor device.

### DETAILED DESCRIPTION

Embodiments of a semiconductor device in accordance with the present disclosure will now be described with reference to the accompanying drawings. In the drawings, elements may not be drawn to scale for simplicity and clarity of illustration. To facilitate understanding, hatching may be omitted from a cross-sectional view, and hatching may be added to a plan view. The accompanying drawings only illustrate embodiments of the present disclosure and are not intended to limit the present disclosure.

This detailed description provides a comprehensive understanding of the methods, apparatuses, and/or systems described. Exemplary embodiments may have different forms, and are not limited to the examples described.

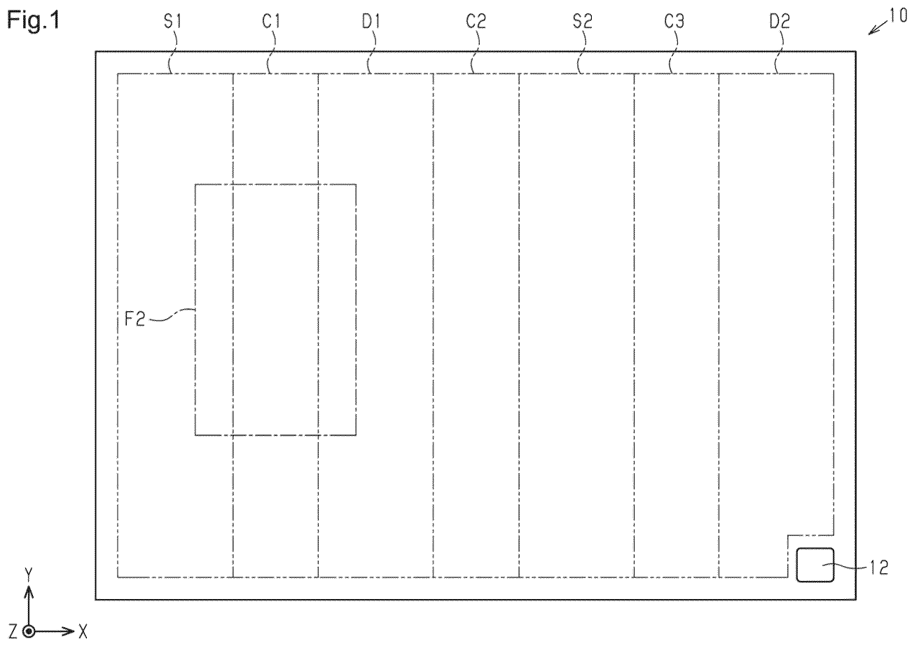

FIG. 1 is a schematic plan view showing an exemplary semiconductor device 10 in an embodiment. As shown in FIG. 1, X-axis, Y-axis, and Z-axis are orthogonal to each another. The term “plan view” as used in the present disclosure is a view of the semiconductor device 10 taken in the Z-axis direction.

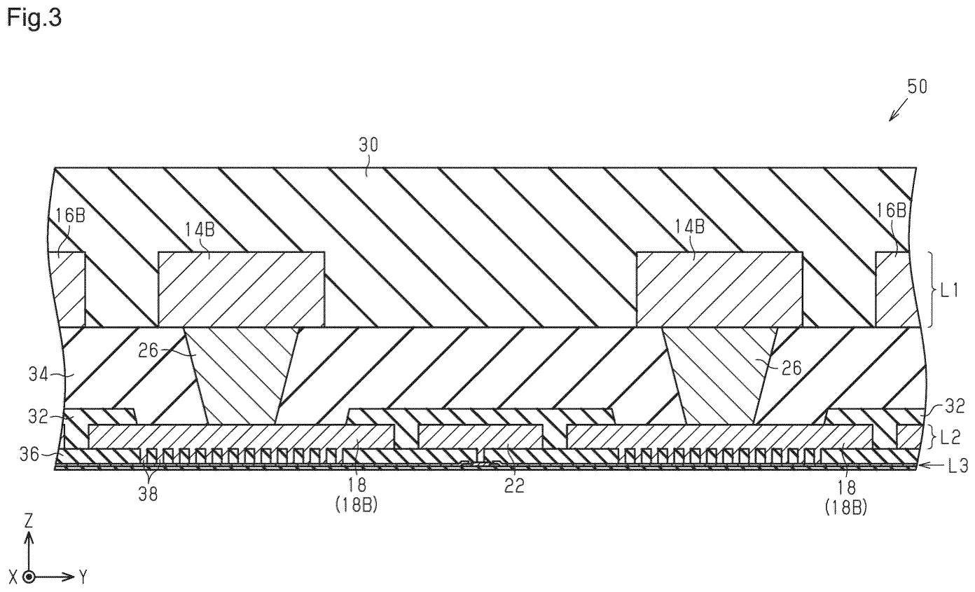

The semiconductor device 10 may include a semiconductor chip that includes a semiconductor element such as a transistor and a multilayer interconnect structure disposed on the semiconductor element. FIG. 1 is a schematic plan view showing mainly a first interconnect layer L1 of the semiconductor device 10 (refer to FIG. 3 for cross-sectional view). In the example shown in FIG. 1, the first interconnect layer L1 may be the uppermost interconnect layer of the semiconductor device 10. In another example, a connection structure is further formed on the first interconnect layer L1. For example, at least one of a metal wire, a metal ribbon, and a metal clip may be formed for packaging the semiconductor device 10.

The semiconductor device 10 may include a gate pad 12. The gate pad 12 is arranged in the first interconnect layer L1. In the example shown in FIG. 1, the gate pad 12 may be formed on a corner of the semiconductor device 10 in plan view. In another example, the gate pad 12 may be formed in a different region of the semiconductor device 10 and may have a different shape and/or a different size.

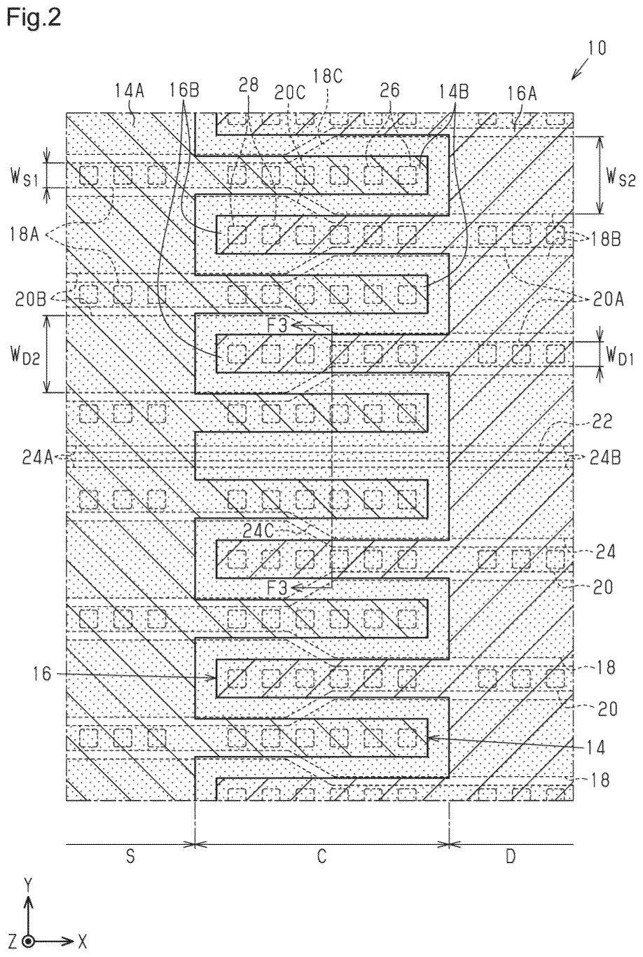

The semiconductor device 10 may include a source pad 14 and a drain pad 16, which will be described in more detail with reference to FIG. 2. The source pad 14 and the drain pad 16 may be formed in a region of the first interconnect layer L1 where the gate pad 12 is not formed. FIG. 1 shows source pad base regions S (S1, S2), drain pad base regions D (D1, D2), and comb-shaped regions (C1, C2, C3) in which the source pad 14 and the drain pad 16 are formed.

The source pad base regions S and the drain pad base regions D are alternately arranged in an X-axis direction (in this specification, also referred to as the first direction). The comb-shaped regions C are arranged between the source pad base regions S and the drain pad base regions D. More specifically, the source pad base regions S and the drain pad base regions D are separated by the comb-shaped regions C in the X-axis direction.

The number of the source pad base regions S, the drain pad base regions D, and the comb-shaped regions C may be set in any manner. In an example, instead of the example shown in FIG. 1, a single source pad base region S, a single drain pad base region D, and a single comb-shaped region C may be arranged.

The arrangement of the source pad 14 and the drain pad 16 in the source pad base regions S, the drain pad base regions D, and the comb-shaped regions C will now be described with reference to FIG. 2.

FIG. 2 is an enlarged plan view of region F2 surrounded by single-dashed lines shown in FIG. 1. Region F2 includes a portion of the source pad base region S1, a portion of the comb-shaped region C1, and a portion of the drain pad base region D1. To facilitate comprehension, the source pad 14 and the drain pad 16 are provided with hatching lines.

The source pad 14 may include a source pad base 14A and source pad extensions 14B extending from the source pad base 14A. The source pad base 14A may be arranged in the source pad base region S1, shown in FIG. 1, and extend in the entire source pad base region S1. The source pad extensions 14B may be arranged in the comb-shaped region C1.

The drain pad 16 may include a drain pad base 16A and drain pad extensions 16B extending from the drain pad base 16A. The drain pad base 16A may be arranged in the drain pad base region D1, shown in FIG. 1, and extend in the entire drain pad base region D1. The drain pad extensions 16B may be arranged in the comb-shaped region C1.

When the source pad base region S1 and the drain pad base region D1 are separated by the comb-shaped region C1 in the X-axis direction, the source pad base 14A and the drain pad base 16A are also separated by the comb-shaped region C1 in the X-axis direction.

The source pad extensions 14B may extend from the source pad base 14A toward the drain pad base 16A. The source pad extensions 14B may extend in the X-axis direction. The source pad extensions 14B are arranged at a predetermined interval in a Y-axis direction (in this specification, also referred to as second direction) orthogonal to the X-axis direction. When the source pad extensions 14B are arranged next to one another in the Y-axis direction, the source pad 14 is comb-shaped in plan view. In the example shown in FIG. 2, the source pad extensions 14B may have a uniform width in the Y-axis direction. In the description hereafter related to FIG. 2, the width refers to a dimension in the Y-axis direction. The width of each source pad extension 14B may be greater than or equal to a width W_{S1} of a first source interconnect part 18A, which will be described later.

The drain pad extensions 16B may extend from the drain pad base 16A toward the source pad base 14A. The drain pad extensions 16B may extend in the X-axis direction. The drain pad extensions 16B are arranged at a predetermined interval in the Y-axis direction. When the drain pad extensions 16B are arranged next to one another in the Y-axis direction, the drain pad 16 is comb-shaped in plan view. In the example shown in FIG. 2, the drain pad extensions 16B may have a uniform width in the Y-axis direction. The width of each drain pad extension 16B may be greater than or equal to the width W_{S1} of the first drain interconnect part 20A, which will be described later. When the drain pad extensions 16B are arranged next to one another in the Y-axis direction, the drain pad 16 is comb-shaped in plan view. In the example shown in FIG. 2, the drain pad extensions 16B may have a uniform width in the Y-axis direction. The width of each drain pad extension 16B may be greater than or equal to a width W_{D1} of the first drain interconnect part 20A, which will be described later.

The comb-shaped source pad 14 and the comb-shaped drain pad 16 are opposed to each other in the X-axis direction. Each of the source pad extensions 14B may be arranged between two of the drain pad extensions 16B, and each of the drain pad extensions 16B may be arranged between two of the source pad extensions 14B. Thus, the source pad extensions 14B and the drain pad extensions 16B are alternately arranged in the Y-axis direction. The source pad extensions 14B and the drain pad extensions 16B are separate in the Y-axis direction.

The drain pad 16 is separate from the source pad 14 in the X-axis direction. More specifically, the drain pad base 16A is separate from the source pad base 14A in the X-axis direction. The distance between the source pad base 14A and the drain pad base 16A (i.e., dimension of the comb-shaped region C1 in the X-axis direction) may be determined taking into consideration on-resistance reduction and packaging reliability. The drain pad extensions 16B are also separate from the source pad extensions 14B. The source pad extensions 14B and the drain pad extensions 16B may be alternately arranged in the Y-axis direction. The alternate arrangement does not necessarily have to be applied to all of the source pad extensions 14B and the drain pad extensions 16B. For example, the drain pad extensions 16B do not have to be arranged between specified two source pad extensions 14B (located above gate interconnect 22 described later).

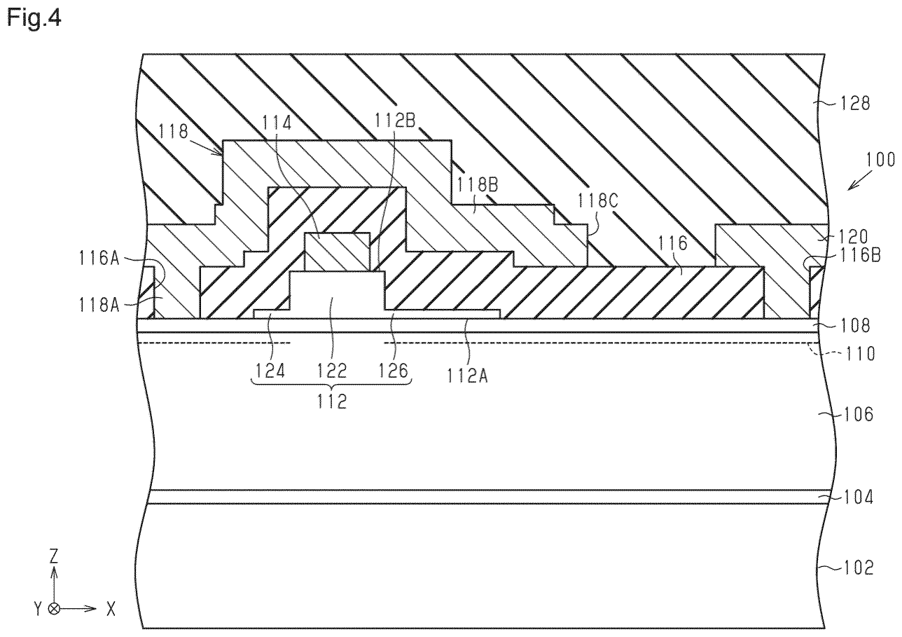

The semiconductor device 10 may further include source interconnects 18 extending in the X-axis direction and drain interconnects 20 extending in the X-axis direction. To facilitate comprehension, in FIG. 2, the source interconnects 18 and the drain interconnects 20 are provided with a dot pattern. The source interconnects 18 and the drain interconnects 20 are arranged in a second interconnect layer L2 (refer to FIG. 3) located below the first interconnect layer L1. The drain interconnects 20 are separate from the source interconnects 18 in the Y-axis direction. The source interconnects 18 and the drain interconnects 20 may be separated from each other and alternately arranged in the Y-axis direction in plan view. The source interconnects 18 may be electrically coupled to a source electrode 118 of a transistor 100, which will be described later with reference to FIG. 4. Also, the drain interconnects 20 may be electrically coupled to a drain electrode 120 of the transistor 100.

Each of the source interconnects 18 may include a first source interconnect part 18A having a width W_{S1} and a second source interconnect part 18B having a width W_{S2} that is greater than the width W_{S1} of the first source interconnect part 18A in the Y-axis direction. In an example, the width W_{S2} of the second source interconnect part 18B may be greater than or equal to 1.5 times the width W_{S1} of the first source interconnect part 18A and less than or equal to 3 times the width W_{S1} of the first source interconnect part 18A.

Each of the source interconnects 18 may further include an intermediate source interconnect part 18C located between the first source interconnect part 18A and the second source interconnect part 18B. The intermediate source interconnect part 18C may have a width that gradually increases toward the second source interconnect part 18B. The first source interconnect part 18A, the intermediate source interconnect part 18C, and the second source interconnect part 18B may be arranged in this order in a direction from the source pad 14 (source pad base 14A) toward the drain pad 16 (drain pad base 16A).

Each of the drain interconnects 20 may include a first drain interconnect part 20A having a width W_{D1} and a second drain interconnect part 20B having a width W_{D2} that is greater than the width W_{D1} of the first drain interconnect part 20A in the Y-axis direction. In an example, the width W_{D2} of the second drain interconnect part 20B may be greater than or equal to 1.5 times the width W_{D1} of the first drain interconnect part 20A and less than or equal to 3 times the width W_{D1} of the first drain interconnect part 20A.

The width W_{S1} of the first source interconnect part 18A may be equal to the width W_{D1} of the first drain interconnect part 20A. The width W_{S2} of the second source interconnect part 18B may be equal to the width W_{D2} of the second drain interconnect part 20B.

Each of the drain interconnects 20 may further include an intermediate drain interconnect part 20C located between the first drain interconnect part 20A and the second drain interconnect part 20B. The intermediate drain interconnect part 20C may have a width that gradually increases toward the second drain interconnect part 20B. The first drain interconnect part 20A, the intermediate drain interconnect part 20C, and the second drain interconnect part 20B may be arranged in this order in a direction from the drain pad 16 (drain pad base 16A) toward the source pad 14 (source pad base 14A).

The second source interconnect part 18B is located adjacent to the first drain interconnect part 20A in the Y-axis direction. The second drain interconnect part 20B is located adjacent to the first source interconnect part 18A in the Y-axis direction. More specifically, the second source interconnect part 18B and the second drain interconnect part 20B, having a relatively large width, are located adjacent to the first drain interconnect part 20A and the first source interconnect part 18A, having a relatively small width.

The intermediate source interconnect part 18C is located adjacent to the intermediate drain interconnect part 20C in the Y-axis direction. In the example shown in FIG. 2, the intermediate source interconnect part 18C and the intermediate drain interconnect part 20C may be arranged near the center of the comb-shaped region C in the X-axis direction.

The semiconductor device 10 may further include a gate interconnect 22 electrically coupled to a gate electrode 114 (refer to FIG. 4) and extending in the X-axis direction and two source interconnects 24 located adjacent to the gate interconnect 22. The gate interconnect 22 may be arranged between the two source interconnects 24 in plan view and have a uniform width in the Y-axis direction. The source interconnects 24, located adjacent to the gate interconnect 22, may have a structure similar to that of the source interconnects 18. More specifically, the source interconnect 24 may include a first source interconnect part 24A and a second source interconnect part 24B having a larger width than the first source interconnect part 24A in the Y-axis direction. However, since the first source interconnect part 24A is located adjacent to the gate interconnect 22 having a uniform width, the first source interconnect part 24A may have a larger width than the first source interconnect part 18A.

The source pad 14 at least partially overlaps the first source interconnect part 18A and the second drain interconnect part 20B in plan view. The first source interconnect part 18A and the second source interconnect part 18B may be at least partially located below the drain pad 16. In contrast, the source pad 14 does not overlap the first drain interconnect part 20A in plan view.

In plan view, the source pad base 14A at least partially overlaps the first source interconnect part 18A and does not overlap the second source interconnect part 18B. In plan view, the source pad base 14A may at least partially overlap the second drain interconnect part 20B.

Each of the source pad extensions 14B may at least partially overlap the first source interconnect part 18A, the intermediate source interconnect part 18C, and the second source interconnect part 18B in plan view. In a region where the source interconnects 18 and the drain interconnects 20 are alternately arranged, the pitch of the source pad extensions 14B in the Y-axis direction may be equal to the pitch of the source interconnects 18 in the Y-axis direction.

The drain pad 16 at least partially overlaps the first drain interconnect part 20A and the second source interconnect part 18B in plan view. The first drain interconnect part 20A and the second drain interconnect part 20B may be at least partially located below the source pad 14. In contrast, the drain pad 16 does not overlap the first source interconnect part 18A in plan view.

In plan view, the drain pad base 16A at least partially overlaps the first drain interconnect part 20A and does not overlap the second drain interconnect part 20B. The drain pad base 16A may at least partially overlap the second source interconnect part 18B.

Each of the drain pad extensions 16B may at least partially overlap the first drain interconnect part 20A, the intermediate drain interconnect part 20C, and the second drain interconnect part 20B in plan view. In a region where the source interconnects 18 and the drain interconnects 20 are alternately arranged, the pitch of the drain pad extensions 16B in the Y-axis direction may be equal to the pitch of the drain interconnects 20 in the Y-axis direction.

The semiconductor device 10 may further include source vias 26 connecting the source pad 14 to the source interconnects 18 and drain vias 28 connecting the drain pad 16 to the drain interconnects 20. The source vias 26 and the drain vias 28 are arranged between the first interconnect layer L1 and the second interconnect layer L2. More specifically, the source vias 26 and the drain vias 28 are formed in an insulation layer 34 (refer to FIG. 3) located between the first interconnect layer L1 and the second interconnect layer L2.

The source vias 26 are separated from each other and arranged in the X-axis direction. Some of the source vias 26 may be arranged at an equal interval in the X-axis direction. In the example shown in FIG. 2, the source vias 26 are not present in the vicinity of the boundary between the source pad base 14A and the source pad extensions 14B in plan view. However, in another example, the source vias 26 may be present in the vicinity of the boundary.

The drain vias 28 are separated from each other and arranged in the X-axis direction. Some of the drain vias 28 may be arranged at an equal interval in the X-axis direction. In the example shown in FIG. 2, the drain vias 28 are not present in the vicinity of the boundary between the drain pad base 16A and the drain pad extensions 16B. However, in another example, the drain vias 28 may be present in the vicinity of the boundary.

The source pad base 14A is connected to the first source interconnect part 18A by one or more of the source vias 26. Since the source pad base 14A does not overlap the second source interconnect part 18B in plan view, the source pad base 14A cannot be connected to the second source interconnect part 18B by the source vias 26. In contrast, each of the source pad extensions 14B is connected to the first source interconnect part 18A and the second source interconnect part 18B by some of the source vias 26. Each of the source pad extensions 14B at least partially overlaps the second source interconnect part 18B in plan view so that the source pad extensions 14B are connected to the second source interconnect part 18B by one or more of the source vias 26.

The drain pad base 16A is connected to the first drain interconnect part 20A by one or more of the drain vias 28. Since the drain pad base 16A does not overlap the second drain interconnect part 20B in plan view, the drain pad base 16A cannot be connected to the second drain interconnect part 20B by the drain vias 28. In contrast, each of the drain pad extensions 16B is connected to the first drain interconnect part 20A and the second drain interconnect part 20B by some of the drain vias 28. Each of the drain pad extensions 16B at least partially overlaps the second drain interconnect part 20B in plan view so that each of the drain pad extensions 16B is connected to the second drain interconnect part 20B by one or more of the drain vias 28.

The elements arranged in the source pad base region S1, the comb-shaped region C1, and the drain pad base region D1, which are shown in FIG. 1, have been described. The same description is applicable to the elements arranged in the source pad base region S2, the comb-shaped regions C2 and C3, and the drain pad base region D2, shown in FIG. 1. Thus, the semiconductor device 10 may include multiple source pads 14 and multiple drain pads 16 alternately arranged in the X-axis direction. In an example, the drain pad 16 shown in FIG. 2 may 2 may further include drain pad extensions 16B extending from the drain pad base 16A toward another source pad base 14A located in the source pad base region S2 (refer to FIG. 1).

FIG. 3 is a schematic cross-sectional view of the semiconductor device 10 taken along line F3-F3 in FIG. 2 showing a multilayer interconnect structure 50 that may be formed above the transistor 100, which will be described later with reference to FIG. 4. In the example shown in FIG. 3, the multilayer interconnect structure 50 may include the first interconnect layer L1, the second interconnect layer L2, and a third interconnect layer L3, sequentially arranged from above. In another example, the multilayer interconnect structure 50 may further include one or more interconnect layers below the third interconnect layer L3.

The gate pad 12 (refer to FIG. 1), the source pad 14 (refer to FIG. 2), and the drain pad 16 (refer to FIG. 2) may be arranged in the first interconnect layer L1. FIG. 3 shows the source pad extensions 14B and the drain pad extensions 16B located in the comb-shaped region C. The semiconductor device 10 may further include an insulation layer 30 insulating the gate pad 12, the source pad 14, and the drain pad 16 from each other. Each pad in the first interconnect layer L1 may be at least partially covered by the insulation layer 30. The insulation layer 30 may have an opening (not shown) that exposes a portion of the upper surface of the pad.

The source interconnects 18, the drain interconnects 20, and the gate interconnect 22 are arranged in the second interconnect layer L2, which is located below the first interconnect layer L1. The semiconductor device 10 may further include an insulation layer 32 insulating the source interconnects 18, the drain interconnects 20, and the gate interconnect 22 from each other. The insulation layer 32 may cover a portion of the upper surface of each interconnect in the second interconnect layer L2.

The semiconductor device 10 may further include an insulation layer 34 covering the source interconnects 18, the drain interconnects 20, and the gate interconnect 22. The insulation layer 34 may be located between the first interconnect layer L1 and the second interconnect layer L2. The source vias 26 and the drain vias 28 are formed in the insulation layer 34. The source pad 14 in the first interconnect layer L1 may be connected to the source interconnects 18 in the second interconnect layer L2 by the source vias 26. The drain pad 16 in the first interconnect layer L1 may be connected to the drain interconnects 20 in the second interconnect layer L2 by the drain vias 28. The insulation layer 34 further includes gate vias, which are not shown. The gate pad 12 in the first interconnect layer L1 is connected to the gate interconnect 22 in the second interconnect layer L2 by the gate vias.

Each interconnect arranged in the second interconnect layer L2 may be electrically coupled to a corresponding electrode in the transistor 100 shown in FIG. 4 through one or more interconnect layers (in the example shown in FIG. 3, the third interconnect layer L3) located below the second interconnect layer L2. Each interconnect arranged in the second interconnect layer L2 may be connected to a corresponding interconnect arranged in the third interconnect layer L3 by vias 38 formed in an insulation layer 36 located between the second interconnect layer L2 and the third interconnect layer L3.

The thickness of interconnect layers may be decreased as the interconnect layers are located in lower layers. For example, the thickness of the source interconnects 18 and the drain interconnects 20 in the second interconnect layer L2 may be smaller than the thickness of the source pad 14 and the drain pad 16 in the first interconnect layer L1.

Interconnects and vias connecting the interconnects arranged in interconnect layers may be formed from any conductive material including cupper (Cu), aluminum (Al), an AlCu alloy, tungsten (W), titanium (Ti), and titanium nitride (TiN). The insulation layers 30, 32, 34, 36 may be formed from any dielectric material including silicon nitride (SiN), silicon oxide (SiO₂), and an insulative resin.

FIG. 4 is a schematic cross-sectional view showing an example of the transistor 100. In the example shown in FIG. 4, the transistor 100 may be a high-electron-mobility transistor including a nitride semiconductor.

The transistor 100 may include a semiconductor substrate 102, a buffer layer 104 formed on the semiconductor substrate 102, an electron transit layer 106 formed on the buffer layer 104, and an electron supply layer 108 formed on the electron transit layer 106.

The semiconductor substrate 102 may be formed from silicon (Si), silicon carbide (SiC), gallium nitride (GaN), sapphire, or other substrate materials. In an example, the semiconductor substrate 102 may be a Si substrate. The semiconductor substrate 102 may have a thickness, for example, in a range of 200 μm to 1500 μm.

The buffer layer 104 may be arranged between the semiconductor substrate 102 and the electron transit layer 106 and may be formed of any material that reduces lattice mismatching between the semiconductor substrate 102 and the electron transit layer 106. The buffer layer 104 may include one or more nitride semiconductor layers. The buffer layer 104 may include at least one of an aluminum nitride (AlN) layer, an aluminum gallium nitride (AlGaN) layer, and a graded AlGaN layer having different aluminum compositions. For example, the buffer layer 104 may include a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 104 may include a first buffer layer that is an AlN layer formed on the semiconductor substrate 102 and a second buffer layer that is an AlGaN layer formed on the AlN layer. In an example, the first buffer layer may be an AlN layer having a thickness of 200 nm. In an example, the second buffer layer may have a structure in which multiple AlGaN layers are stacked. To inhibit current leakage of the buffer layer 104, a portion of the buffer layer 104 may be doped with an impurity so that the buffer layer 104 becomes semi-insulating. In this case, the impurity is, for example, carbon (C) or iron (Fe). The concentration of the impurity may be, for example, greater than or equal to 4×10¹⁶ cm⁻³.

The electron transit layer 106 is composed of a nitride semiconductor and may be, for example, a GaN layer. The thickness of the electron transit layer 106 may be, for example, in a range of 300 nm to 2 μm, and more preferably, in a range of 300 nm to 400 nm. In an example, the thickness of the electron transit layer 106 is 350 nm.

To inhibit current leakage of the electron transit layer 106, the electron transit layer 106 may be partially doped with an impurity so that the electron transit layer 106 excluding its surface region becomes semi-insulating. In this case, the impurity is, for example, C. The concentration of the impurity may be, for example, greater than or equal to 1×10¹⁹ cm⁻³ at a peak concentration. More specifically, the electron transit layer 106 may include GaN layers having different impurity concentrations, for example, a C-doped GaN layer and a non-doped GaN layer. The C concentration in the C-doped GaN layer may be in a range of 9×10¹⁸ cm⁻³ to 9×10¹⁹ cm⁻³.

The electron supply layer 108 is composed of a nitride semiconductor having a band gap that is larger than that of the electron transit layer 106 and may be, for example, an AlGaN layer. The band gap increases as the Al composition increases. Therefore, the electron supply layer 108, which is an AlGaN layer, has a larger band gap than the electron transit layer 106, which is a GaN layer. In an example, the electron supply layer 108 is formed from Al_{z}Ga_{1-z} N, where 0.1<z<0.4, and more preferably, 0.2<z<0.3. In an example, z=0.25. The electron supply layer 108 may have a thickness in a range of 5 nm to 20 nm. In an example, the thickness of the electron supply layer 108 may be in a range of 8 nm to 15 nm.

The electron transit layer 106 and the electron supply layer 108 are formed from nitride semiconductors having different lattice constants. A lattice-mismatching junction between the electron transit layer 106 and the electron supply layer 108 imposes strain on the electron supply layer 108. The strain induces a two-dimensional electron gas 110 (2DEG) in the electron transit layer 106. The 2DEG 110 spreads in the electron transit layer 106 at a location close to the heterojunction interface between the electron transit layer 106 and the electron supply layer 108 (for example, approximately a few nanometers away from the interface). The 2DEG 110 is used as a current path (channel) of the transistor 100.

The transistor 100 may further include a gate layer 112 formed on the electron supply layer 108, a gate electrode 114 formed on the gate layer 112, a passivation layer 116, the source electrode 118, and the drain electrode 120. The passivation layer 116 covers the electron supply layer 108, the gate layer 112, and the gate electrode 114 and includes a first opening 116A and a second opening 116B. The source electrode 118 is in contact with the electron supply layer 108 through the first opening 116A. The drain electrode 120 is in contact with the electron supply layer 108 through the second opening 116B.

The gate layer 112 is formed on a portion of the electron supply layer 108 and composed of a nitride semiconductor including an acceptor impurity. The gate layer 112 may be formed of any material having a band gap that is smaller than that of the electron supply layer 108, which is, for example, an AlGaN layer. In an example, the gate layer 112 is a GaN layer (p-type GaN layer) doped with an acceptor impurity. The acceptor impurity may include at least one of zinc (Zn), magnesium (Mg), and carbon (C). The maximum concentration of the acceptor impurity in the gate layer 112 is, for example, in a range of 7×10¹⁸ cm⁻³ to 1×10²⁰ cm⁻³. The transistor 100, which includes the gate layer 112 composed of a nitride semiconductor including an acceptor impurity, performs a normally-off operation.

The gate layer 112 includes a bottom surface 112A in contact with the electron supply layer 108 and an upper surface 112B opposite to the bottom surface 112A. The gate electrode 114 may be formed on the upper surface 112B of the gate layer 112.

In the example shown in FIG. 4, the gate layer 112 includes a ridge 122 including the upper surface 112B, on which the gate electrode 114 is formed, and two extensions 124 and 126 (first extension 124 and second extension 126) extending outward from the ridge 122 in plan view.

In plan view, the first extension 124 extends from the ridge 122 toward the first opening 116A. The first extension 124 is separate from the first opening 116A.

In plan view, the second extension 126 extends from the ridge 122 toward the second opening 116B. The second extension 126 is separate from the second opening 116B.

The ridge 122 is located between the first extension 124 and the second extension 126 and is formed integrally with the first extension 124 and the second extension 126. Since the gate layer 112 includes the first extension 124 and the second extension 126, the bottom surface 112A may be greater in area than the upper surface 112B. In the example shown in FIG. 4, the second extension 126 extends longer than the first extension 124 outward from the ridge 122 in plan view.

The ridge 122 corresponds to a relatively thick portion of the gate layer 112 and may have a thickness in a range of 80 nm to 150 nm. The thickness of the gate layer 112, particularly, the ridge 122, may be determined taking into consideration parameters including the gate threshold voltage. In an example, the thickness of the gate layer 112 (the ridge 122) is greater than 110 nm.

Each of the first extension 124 and the second extension 126 is smaller in thickness than the ridge 122. In an example, the thickness of each of the first extension 124 and the second extension 126 may be less than or equal to one-half of the thickness of the ridge 122.

In the example shown in FIG. 4, each of the extensions 124 and 126 is a flat portion having a substantially constant thickness. In this specification, “substantially constant thickness” refers to a thickness being within a manufacturing variation range (for example, 20%). Alternatively, each of the extensions 124 and 126 may include a tapered portion having a thickness that gradually decreases as the ridge 122 becomes farther away in a region abutting the ridge 122. Each of the extensions 124 and 126 may include a flat portion having a substantially constant thickness in a region located away from the ridge 122 by a predetermined distance. In an example, the flat portion may have a thickness in a range of 5 nm to 25 nm.

The gate electrode 114 is formed on the upper surface 112B of the gate layer 112. In other words, since the ridge 122 includes the upper surface 112B of the gate layer 112, the gate electrode 114 is formed on the ridge 122 of the gate layer 112. The gate electrode 114 is formed of one or more metal layers, which is, for example, a TiN layer. Alternatively, the gate electrode 114 may include a first metal layer composed of Ti and a second metal layer arranged on the first metal layer and composed of TiN. The gate electrode 114 may have a thickness that is, for example, in a range of 50 nm to 200 nm. The gate electrode 114 may form a Schottky junction with the gate layer 112.

The passivation layer 116 covers the electron supply layer 108, the gate layer 112, and the gate electrode 114 and includes the first opening 116A and the second opening 116B. The first opening 116A and the second opening 116B of the passivation layer 116 are separate from the gate layer 112. The gate layer 112 is arranged between the first opening 116A and the second opening 116B. More specifically, the gate layer 112 may be arranged between the first opening 116A and the second opening 116B at a position closer to the first opening 116A than to the second opening 116B. The passivation layer 116 extends on the upper surface of the electron supply layer 108, the side surface and the upper surface 112B of the gate layer 112, and the side surface and the upper surface of the gate electrode 114. Thus, the passivation layer 116 includes a non-flat surface.

The source electrode 118 and the drain electrode 120 may be composed of one or more metal layers (e.g., any combination of a Ti layer, a TiN layer, an Al layer, an AlSiCu layer, an AlCu layer, and the like). At least a portion of the source electrode 118 fills the first opening 116A. At least a portion of the drain electrode 120 fills the second opening 116B. Each of the source electrode 118 and the drain electrode 120 is in ohmic contact with the 2DEG 110 present immediately below the electron supply layer 108 through the first opening 116A and the second opening 116B, respectively.

The source electrode 118 includes a source contact 118A filling the first opening 116A and a source field plate 118B covering the passivation layer 116. The source field plate 118B is continuous with the source contact 118A and is formed integrally with the source contact 118A. In plan view, the source field plate 118B includes an end 118C located between the second opening 116B and the gate layer 112 in plan view. The source field plate 118B extends from the source contact 118A to the end 118C along the surface of the passivation layer 116 toward the drain electrode 120 but is separate from the drain electrode 120. Since the source field plate 118B extends along the non-flat surface of the passivation layer 116, the source field plate 118B includes a non-flat surface in the same manner. In a state in which no gate voltage is applied to the gate electrode 114, that is, in the zero bias state, when a drain voltage is applied to the drain electrode 120, the source field plate 118B lessens the concentration of electric field in the vicinity of the end of the gate electrode 114.

The multilayer interconnect structure 50, which has been described with reference to FIG. 3, is formed on the transistor 100. In the example shown in FIG. 4, an interconnect layer (e.g., third interconnect layer L3 shown in FIG. 3) may be formed on an insulation layer 128 covering the source electrode 118, the drain electrode 120, and the passivation layer 116 of the transistor 100.

### Operation

The operation of the semiconductor device 10 of the present embodiment will be described below.

In the present embodiment of the semiconductor device 10, in plan view, the source pad 14 at least partially overlaps the first source interconnect part 18A, having a relatively small width, and the second drain interconnect part 20B, having a relatively large width. The drain pad 16 at least partially overlaps the first drain interconnect part 20A, having a relatively small width, and the second source interconnect part 18B, having a relatively large width, in plan view.

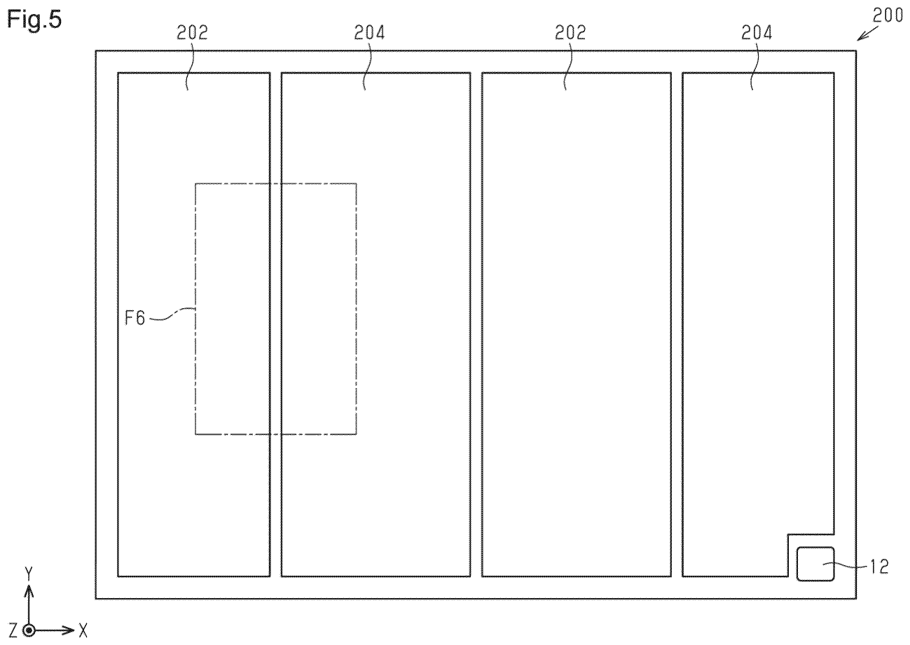

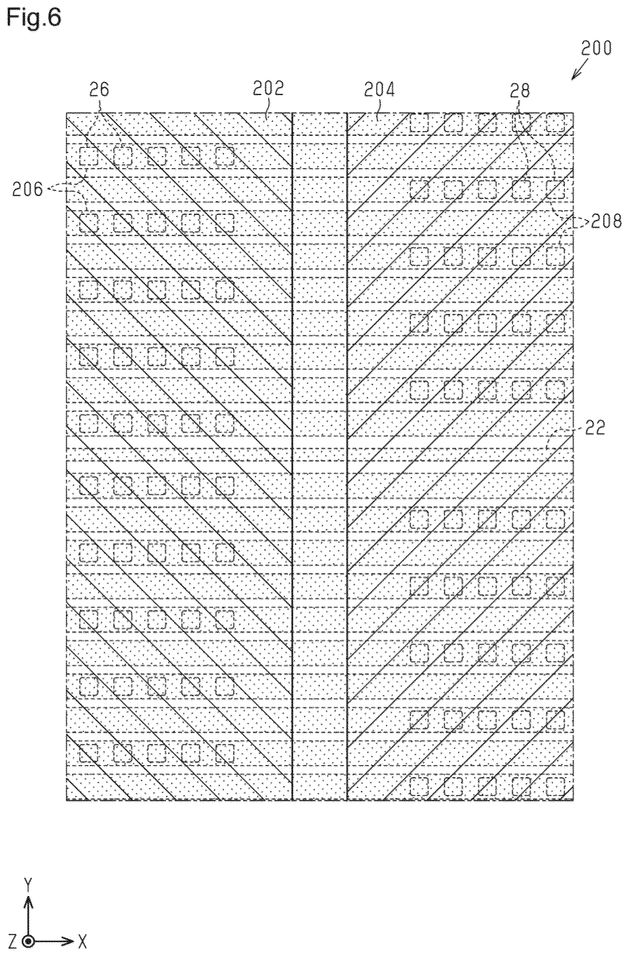

This structure decreases the resistance of the current path extending from the source pad 14 to the source electrode 118 and the resistance of the current path extending from the drain electrode 120 to the drain pad 16. Thus, the on-resistance of the transistor 100 is decreased. The effect of decreasing the on-resistance of the semiconductor device 10 will now be further described with reference to a comparative example of a semiconductor device 200 shown in FIGS. 5 and 6.

FIG. 5 is a schematic plan view showing a comparative example of the semiconductor device 200. In FIG. 5, the same reference characters are given to those elements that are the same as the corresponding elements of the semiconductor device 10. Such elements will not be described in detail.

The semiconductor device 200 includes source pads 202 and drain pads 204. The source pads 202 are rectangular in plan view and do not include an extension such as the source pad extensions 14B shown in FIG. 2. The drain pads 204 are also rectangular in plan view and do not include an extension such as the drain pad extensions 16B shown in FIG. 2. The source pads 202 and the drain pads 204 are separated from each other and alternately arranged in the X-axis direction.

FIG. 6 is an enlarged plan view of region F6 surrounded by single-dashed lines shown in FIG. 5. Region F6 includes a portion of the source pads 202 and a portion of the drain pads 204. To facilitate comprehension, the source pad 202 and the drain pad 204 are provided with hatching lines. The semiconductor device 200 of the comparative example may further include source interconnects 206 extending in the X-axis direction and drain interconnects 208 extending in the X-axis direction. In FIG. 6, the source interconnects 206 and the drain interconnects 208 are provided with a dot pattern.

The source interconnects 206 and the drain interconnects 208 are arranged in the second interconnect layer L2 located below the first interconnect layer L1, in which the source pads 202 and the drain pads 204. The source interconnects 206 and the drain interconnects 208 are separated from each other and alternately arranged in the Y-axis direction. The source interconnects 206 may be electrically coupled to the source electrode 118 (refer to FIG. 4) of the transistor 100. The drain interconnects 208 may be electrically coupled to the drain electrode 120 (refer to FIG. 4) of the transistor 100.

The semiconductor device 200 of the comparative example differs from the semiconductor device 10 shown in FIG. 2 in that the source interconnects 206 and the drain interconnects 208 each have a uniform width irrespective of the positional relationship with the source pads 202 and the drain pads 204.

Portions of the source interconnects 206 extending under the source pad 202 are connected to the source pad 202, located immediately above, by the source vias 26. As a result, the current path is relatively long between the source pad 202 and portions of the source interconnects 206 extending under the drain pad 204. In the same manner, portions of the drain interconnects 208 extending under the drain pad 204 are connected to the drain pad 204, located immediately above, by the drain vias 28. As a result, the current path is relatively long between the drain pad 204 and portions of the drain interconnects 208 extending under the source pad 202. Hence, resistance of the source interconnects 206 extending under the drain pads 204 and resistance of the drain interconnects 208 extending under the source pads 202 have a relatively large effect on on-resistance of the transistor 100.

In the semiconductor device 10 of the present embodiment, in plan view, the source pad 14 at least partially overlaps the second drain interconnect part 20B, having a relatively large width. Although the current path between the drain pad 16 and the drain interconnects 20 extending under the source pad 14 is relatively long, the resistance of the current path is relatively low because of the relatively large width of the second drain interconnect part 20B. Also, in plan view, the drain pad 16 at least partially overlaps the second source interconnect part 18B, having a relatively large width. Although the current path between the source pad 14 and the source interconnects 18 extending under the drain pad 16 is relatively long, the resistance of the current path is relatively low because of the relatively large width of the second source interconnect part 18B. As a result, in the semiconductor device 10 of the present embodiment, the on-resistance of the transistor 100 is decreased by approximately 25% as compared to the semiconductor device 200 having the same chip size.

The source interconnects 18 extending under the source pad 14 and the drain interconnects 20 extending under the drain pad 16 are connected to the respective pads, located immediately above, by the respective vias. Hence, even when the source interconnects 18 extending under the source pad 14 and the drain interconnects 20 extending under the drain pad 16 have a relatively small width, the effect on the on-resistance of the transistor 100 is relatively small. In the semiconductor device 10, the second source interconnect part 18B and the second drain interconnect part 20B, having a relatively large width, are located adjacent to the first drain interconnect part 20A and the first source interconnect part 18A, having a relatively small width, in the Y-axis direction. This decreases the on-resistance of the transistor 100 while minimizing decreases in the number of the source interconnects 18 and the drain interconnects 20 that are allowed to be arranged.

### Advantages

The semiconductor device 10 of the present embodiment has the following advantages.

(1) In plan view, the source pad 14 at least partially overlaps the first source interconnect part 18A, having a relatively small width, and the second drain interconnect part 20B, having a relatively large width. The drain pad 16 at least partially overlaps the first drain interconnect part 20A, having a relatively small width, and the second source interconnect part 18B, having a relatively large width, in plan view.

This structure decreases the resistance of the current path extending from the source pad 14 to the source electrode 118 and the resistance of the current path extending from the drain electrode 120 to the drain pad 16. Thus, the on-resistance of the transistor 100 is decreased.

(2) The source pad extension 14B at least partially overlaps the second source interconnect part 18B in plan view so that the source pad extension 14B is connected to the second source interconnect part 18B by one or more of the source vias 26. The drain pad extension 16B at least partially overlaps the second drain interconnect part 20B in plan view so that the drain pad extension 16B is connected to the second drain interconnect part 20B by one or more of the drain vias 28.

In this structure, the source pad extension 14B and the drain pad extension 16B are connected to the second source interconnect part 18B and the second drain interconnect part 20B, having a relatively large width. This lessens the concentration of current on the connected portions. As a result, the reliability of the interconnects is improved as compared to a structure in which the extensions are connected to only interconnects having a relatively small width.

### First Modified Example

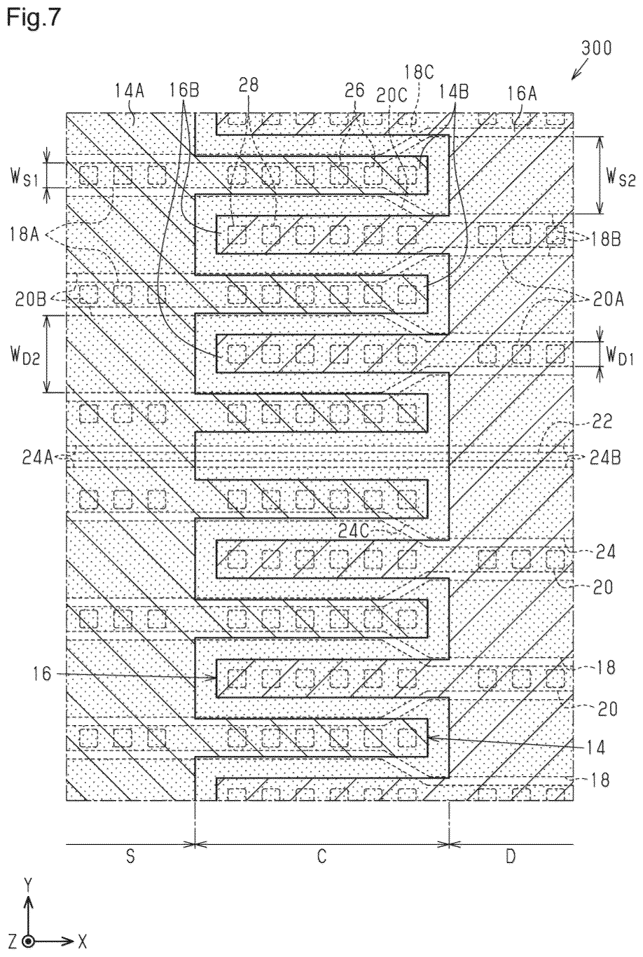

FIG. 7 is an enlarged plan view showing a semiconductor device 300 of a first modified example corresponding to region F2 shown in FIG. 2 (portion of the source pad base region S1, portion of the comb-shaped region C1, and portion of the drain pad base region D1). In FIG. 7, the same reference characters are given to those elements that are the same as the corresponding elements of the semiconductor device 10. Such elements will not be described in detail.

In the semiconductor device 300, the intermediate source interconnect part 18C and the intermediate drain interconnect part 20C are located toward the drain pad base region D in the comb-shaped region C. As a result, in plan view, each of the source pad extensions 14B at least partially overlaps the intermediate source interconnect part 18C and does not overlap the second source interconnect part 18B. Thus, each of the source pad extensions 14B is connected to the intermediate source interconnect part 18C by the source vias 26 but is not connected to the second source interconnect part 18B.

The intermediate source interconnect part 18C has a generally larger width than the first source interconnect part 18A. Thus, the concentration of current on the connected portion is lessened as compared to a structure in which the source pad extensions 14B are connected to only the first source interconnect part 18A. Therefore, the semiconductor device 300 also decreases the on-resistance of the transistor 100 (refer to FIG. 4) while improving the reliability of the interconnects.

### Second Modified Example

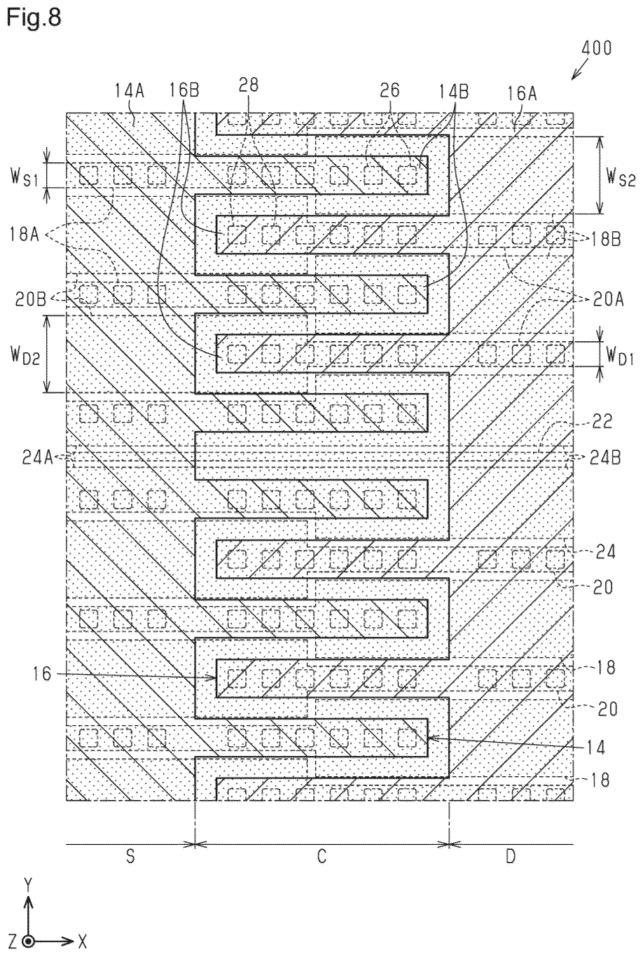

FIG. 8 is an enlarged plan view showing a semiconductor device 400 of a second modified example corresponding to region F2 shown in FIG. 2 (portion of the source pad base region S1, portion of the comb-shaped region C1, and portion of the drain pad base region D1). In FIG. 8, the same reference characters are given to those elements that are the same as the corresponding elements of the semiconductor device 10. Such elements will not be described in detail.

In the semiconductor device 400, the source interconnects 18 do not include the intermediate source interconnect part 18C, and the drain interconnects 20 do not include the intermediate drain interconnect part 20C. Also, the source interconnects 24 do not include an intermediate source interconnect part 24C. Thus, the first source interconnect part 18A, the first drain interconnect part 20A, and the first source interconnect part 24A are respectively located adjacent to the second source interconnect part 18B, the second drain interconnect part 20B, and the second source interconnect part 24B. In the same manner as the semiconductor device 10, the semiconductor device 400 decreases the on-resistance of the transistor 100 (refer to FIG. 4).

### Third Modified Example

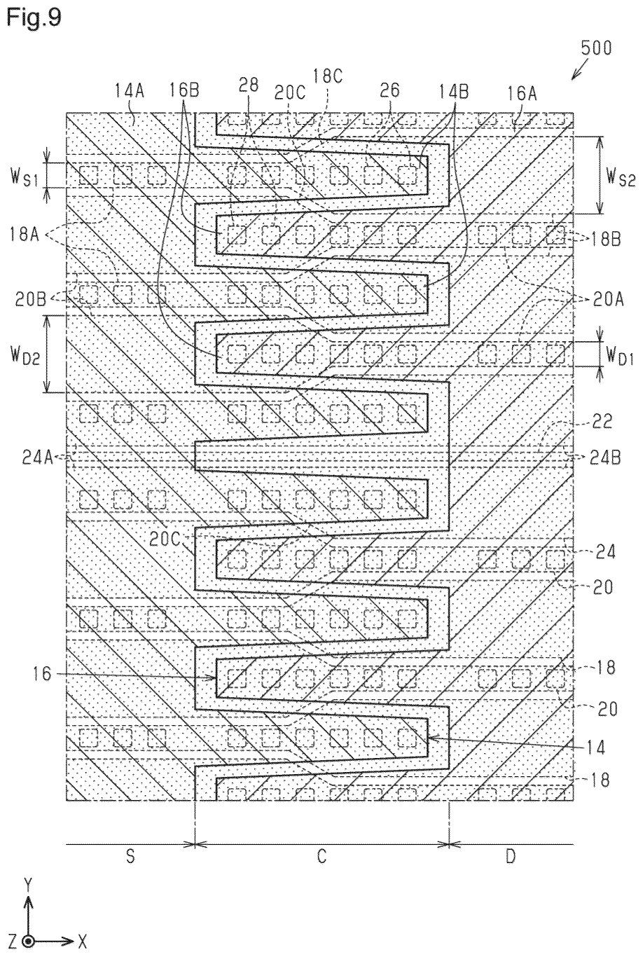

FIG. 9 is an enlarged plan view showing a semiconductor device 500 of a third modified example corresponding to region F2 shown in FIG. 2 (portion of the source pad base region S1, portion of the comb-shaped region C1, and portion of the drain pad base region D1). In FIG. 9, the same reference characters are given to those elements that are the same as the corresponding elements of the semiconductor device 10. Such elements will not be described in detail.

In the semiconductor device 500, the source pad extensions 14B and the drain pad extensions 16B do not necessarily have to have a uniform width in the Y-axis direction. As shown in FIG. 9, the source pad extensions 14B may have a width that gradually increases toward the source pad base 14A. Also, the drain pad extensions 16B may have a width that gradually increases toward the drain pad base 16A. This structure mitigates a sudden change in the width of the boundary between the source pad base 14A and the source pad extension 14B and the boundary between the drain pad base 16A and the drain pad extension 16B. In the same manner as the semiconductor device 10, the semiconductor device 500 decreases the on-resistance of the transistor 100 (refer to FIG. 4).

### Other Modified Examples

The embodiments and the modified examples described above may be modified as follows.

The transistor 100 may be any transistor formed from a material and/or having a structure differing from that described with reference to FIG. 4. In an example, the transistor 100 may be a silicon-based metal-oxide-semiconductor field effect transistor (silicon MOSFET). Alternatively, the transistor 100 may be a depletion mode high-electron-mobility transistor that does not include a gate layer composed of a nitride semiconductor including an acceptor impurity.

In the semiconductor device 10, the source pad 202 and the drain pad 204 of the semiconductor device 200 in the comparative example shown in FIG. 6 may be used instead of the source pad 14 and the drain pad 16 shown in FIG. 2. In plan view, the source pad 202 at least partially overlaps the second drain interconnect part 20B, having a relatively large width. In plan view, the drain pad 204 at least partially overlaps the second source interconnect part 18B, having a relatively large width. This structure also decreases the resistance of the current path extending from the source pad 202 to the source electrode 118 and the resistance of the current path extending from the drain electrode 120 to the drain pad 204. Thus, the on-resistance of the transistor 100 is decreased.

In the semiconductor device 10, the two source interconnects 24, which are located adjacent to the gate interconnect 22, may have the same structure as the source interconnects 18. More specifically, the first source interconnect part 24A may have substantially the same width as the first source interconnect part 18A, and the second source interconnect part 24B may have substantially the same width as the second source interconnect part 18B.

The semiconductor device 10 may include one or more additional source interconnects having a uniform width in addition to the source interconnects 18. The semiconductor device 10 may also include one or more additional drain interconnects having a uniform width in addition to the drain interconnects 20.

The semiconductor device 10 may include one or more additional source interconnects that do not include the intermediate source interconnect part 18C in addition to the source interconnects 18, which include the intermediate source interconnect part 18C. In the same manner, the semiconductor device 10 may include one or more additional drain interconnects that do not include the intermediate drain interconnect part 20C in addition to the drain interconnects 20, which include the intermediate drain interconnect part 20C.

One or more of the various examples described in this specification may be combined within a range where there is no technical inconsistency.

In this specification, the term “coupled” may mean a direct or indirect coupling between two or more elements. That is, two or more elements may be coupled with or without another element located between the two or more elements. The term “connected” may mean that two or more elements are in direct contact with each other unless otherwise clearly indicated in the context. In an example, “A is connected to C via B” or “A is connected to C by B” may mean that A is in direct contact with B while B is in direct contact with C.

In this specification, “at least one of A and B” should be understood to mean “only A, or only B, or both A and B.”

In this specification, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer.

The directional terms used in this specification such as “vertical,” “horizontal,” “above,” “below,” “top,” “bottom,” “frontward,” “backward,” “longitudinal,” “lateral,” “left,” “right,” “front,” and “back” will depend upon a particular orientation of the device being described and illustrated. The present disclosure may include various alternative orientations. Therefore, the directional terms should not be narrowly construed.

For example, the Z-axis direction as referred to in this specification does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

### Clauses

Technical concepts that can be understood from each of the above embodiments and modified examples will now be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.

### [Clause 1]

A semiconductor device (10), including:
a transistor (100) including a gate electrode (114), a source electrode (118), and a drain electrode (120);
a source interconnect (18) electrically coupled to the source electrode (118) and extending in a first direction;
a drain interconnect (20) electrically coupled to the drain electrode (120) and extending in the first direction, the drain interconnect (20) being separate from the source interconnect (18) in a second direction orthogonal to the first direction in plan view;
a source pad (14) electrically coupled to the source interconnect (18); and
a drain pad (16) separated from the source pad (14) in the first direction and electrically coupled to the drain interconnect (20), in which
the source interconnect (18) includes a first source interconnect part (18A) having a width (W_{S1}) and a second source interconnect part (18B) having a width (W_{S2}) that is greater than the width (W_{S1}) of the first source interconnect part (18A) in the second direction,
the drain interconnect (20) includes a first drain interconnect part (20A) having a width (W_{D1}) and a second drain interconnect part (20B) having a width (W_{D2}) that is greater than the width (W_{D1}) of the first drain interconnect part (20A) in the second direction,
the source pad (14) at least partially overlaps the first source interconnect part (18A) and the second drain interconnect part (20B) in plan view, and
the drain pad (16) at least partially overlaps the first drain interconnect part (20A) and the second source interconnect part (18B) in plan view.

### [Clause 2]

The semiconductor device according to clause 1, in which
the width (W_{S2}) of the second source interconnect part (18B) is greater than or equal to 1.5 times the width (W_{S1}) of the first source interconnect part (18A) and less than or equal to 3 times the width (W_{S1}) of the first source interconnect part (18A), and
the width (W_{D2}) of the second drain interconnect part (20B) is greater than or equal to 1.5 times the width (W_{D1}) of the first drain interconnect part (20A) and less than or equal to 3 times the width (W_{D1}) of the first drain interconnect part (20A).

### [Clause 3]

The semiconductor device according to clause 1 or 2, in which the width (W_{S1}) of the first source interconnect part (18A) is equal to the width
(W_{D1}) of the first drain interconnect part (20A), and the width (W_{S2}) of the second source interconnect part (18B) is equal to the width
(W_{D2}) of the second drain interconnect part (20B).

### [Clause 4]

The semiconductor device according to any one of clauses 1 to 3, in which
the source interconnect (18) further includes an intermediate source interconnect part (18C) located between the first source interconnect part (18A) and the second source interconnect part (18B),
the intermediate source interconnect part (18C) has a width that gradually increases toward the second source interconnect part (18B),
the drain interconnect (20) further includes an intermediate drain interconnect part (20C) located between the first drain interconnect part (20A) and the second drain interconnect part (20B), and
the intermediate drain interconnect part (20C) has a width that gradually increases toward the second drain interconnect part (20B).

### [Clause 5]

The semiconductor device according to clause 4, in which
the first source interconnect part (18A), the intermediate source interconnect part (18C), and the second source interconnect part (18B) are arranged in this order in a direction from the source pad (14) toward the drain pad (16), and
the first drain interconnect part (20A), the intermediate drain interconnect part (20C), and the second drain interconnect part (20B) are arranged in this order in a direction from the drain pad (16) toward the source pad (14).

### [Clause 6]

The semiconductor device according to any one of clauses 1 to 5, further including:
a gate interconnect (22) electrically coupled to the gate electrode (114) and extending in the first direction.

### [Clause 7]

The semiconductor device according to any one of clauses 1 to 6, in which
the source pad (14) includes a source pad base (14A) at least partially overlapping the second drain interconnect part (20B) in plan view and a source pad extension (14B) extending from the source pad base (14A),
the drain pad (16) includes a drain pad base (16A) at least partially overlapping the second source interconnect part (18B) in plan view and a drain pad extension (16B) extending from the drain pad base (16A),
the drain pad base (16A) is separate from the source pad base (14A) in the first direction,
the source pad extension (14B) extends from the source pad base (14A) toward the drain pad base (16A),
the drain pad extension (16B) extends from the drain pad base (16A) toward the source pad base (14A),
the source pad extension (14B) is separate from the drain pad extension (16B) in the second direction,
the semiconductor device (10) further includes:
source vias (26) connecting the source pad (14) to the source interconnect (18); and
drain vias (28) connecting the drain pad (16) to the drain interconnect (20),
the source pad extension (14B) at least partially overlaps the second source interconnect part (18B) in plan view so that the source pad extension (14B) is connected to the second source interconnect part (18B) by one or more of the source vias (26), and
the drain pad extension (16B) at least partially overlaps the second drain interconnect part (20B) in plan view so that the drain pad extension (16B) is connected to the second drain interconnect part (20B) by one or more of the drain vias (28).

### [Clause 8]

The semiconductor device according to clause 7, in which
in plan view, the source pad base (14A) at least partially overlaps the first source interconnect part (18A) and does not overlap the second source interconnect part (18B), and
in plan view, the drain pad base (16A) at least partially overlaps the first drain interconnect part (20A) and does not overlap the second drain interconnect part (20B).

### [Clause 9]

The semiconductor device according to clause 7 or 8, in which
the source pad extension (14B) is connected to the first source interconnect part (18A) and the second source interconnect part (18B) by two or more of the source vias (26), and
the drain pad extension (16B) is connected to the first drain interconnect part (20A) and the second drain interconnect part (20B) by two or more of the drain vias (28).

### [Clause 10]

The semiconductor device according to any one of clauses 7 to 9, further including:
source pads and drain pads alternately arranged in the first direction, in which
the source pad (14) is one of the source pads, and
the drain pad (16) is one of the drain pads.

### [Clause 11]

The semiconductor device according to any one of clauses 7 to 10, further including: a multilayer interconnect structure including a first interconnect layer (L1) and a second interconnect layer (L2) located below the first interconnect layer (L1), in which
the source pad (14) and the drain pad (16) are arranged in the first interconnect layer (L1),
the source interconnect (18) and the drain interconnect (20) are arranged in the second interconnect layer (L2), and
the source vias (26) and the drain vias (28) are arranged between the first interconnect layer (L1) and the second interconnect layer (L2).

### [Clause 12]

The semiconductor device according to clause 11, in which the source interconnect (18) and the drain interconnect (20) are respectively connected to the source electrode (118) and the drain electrode (120) through one or more interconnect layers (L3).

### [Clause 13]

The semiconductor device according to any one of clauses 1 to 12, in which the transistor (100) is a high-electron-mobility transistor including a nitride semiconductor.

### [Clause 14]

The semiconductor device according to any one of clauses 1 to 12, in which the transistor (100) is a silicon MOSFET.

### [Clause 15]

The semiconductor device according to clause 13, in which the transistor (100) further includes:
an electron transit layer (106) composed of a nitride semiconductor;
an electron supply layer (108) formed on the electron transit layer (106) and composed of a nitride semiconductor having a band gap that is larger than that of the electron transit layer (106); and
a gate layer (112) formed on a portion of the electron supply layer (108) and composed of a nitride semiconductor including an acceptor impurity.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A semiconductor device, comprising:
a transistor including a gate electrode, a source electrode, and a drain electrode;
a source interconnect electrically coupled to the source electrode and extending in a first direction;
a drain interconnect electrically coupled to the drain electrode and extending in the first direction, the drain interconnect being separate from the source interconnect in a second direction orthogonal to the first direction in plan view;
a source pad electrically coupled to the source interconnect; and
a drain pad separated from the source pad in the first direction and electrically coupled to the drain interconnect, wherein
the source interconnect includes a first source interconnect part having a width and a second source interconnect part having a width that is greater than the width of the first source interconnect part in the second direction,
the drain interconnect includes a first drain interconnect part having a width and a second drain interconnect part having a width that is greater than the width of the first drain interconnect part in the second direction,
the source pad at least partially overlaps the first source interconnect part and the second drain interconnect part in plan view, and
the drain pad at least partially overlaps the first drain interconnect part and the second source interconnect part in plan view.

2. The semiconductor device according to claim 1, wherein
the width of the second source interconnect part is greater than or equal to 1.5 times the width of the first source interconnect part and less than or equal to 3 times the width of the first source interconnect part, and
the width of the second drain interconnect part is greater than or equal to 1.5 times the width of the first drain interconnect part and less than or equal to 3 times the width of the first drain interconnect part.

3. The semiconductor device according to claim 1, wherein
the width of the first source interconnect part is equal to the width of the first drain interconnect part, and
the width of the second source interconnect part is equal to the width of the second drain interconnect part.

4. The semiconductor device according to claim 1, wherein
the source interconnect further includes an intermediate source interconnect part located between the first source interconnect part and the second source interconnect part,
the intermediate source interconnect part has a width that gradually increases toward the second source interconnect part,
the drain interconnect further includes an intermediate drain interconnect part located between the first drain interconnect part and the second drain interconnect part, and
the intermediate drain interconnect part has a width that gradually increases toward the second drain interconnect part.

5. The semiconductor device according to claim 4, wherein
the first source interconnect part, the intermediate source interconnect part, and the second source interconnect part are arranged in this order in a direction from the source pad toward the drain pad, and
the first drain interconnect part, the intermediate drain interconnect part, and the second drain interconnect part are arranged in this order in a direction from the drain pad toward the source pad.

6. The semiconductor device according to claim 1, further comprising:
a gate interconnect electrically coupled to the gate electrode and extending in the first direction.

7. The semiconductor device according to claim 1, wherein
the source pad includes a source pad base at least partially overlapping the second drain interconnect part in plan view and a source pad extension extending from the source pad base,
the drain pad includes a drain pad base at least partially overlapping the second source interconnect part in plan view and a drain pad extension extending from the drain pad base,
the drain pad base is separate from the source pad base in the first direction,
the source pad extension extends from the source pad base toward the drain pad base,
the drain pad extension extends from the drain pad base toward the source pad base,
the source pad extension is separate from the drain pad extension in the second direction,
the semiconductor device further includes:
source vias connecting the source pad to the source interconnect; and
drain vias connecting the drain pad to the drain interconnect,
the source pad extension at least partially overlaps the second source interconnect part in plan view so that the source pad extension is connected to the second source interconnect part by one or more of the source vias, and
the drain pad extension at least partially overlaps the second drain interconnect part in plan view so that the drain pad extension is connected to the second drain interconnect part by one or more of the drain vias.

8. The semiconductor device according to claim 7, wherein
in plan view, the source pad base at least partially overlaps the first source interconnect part and does not overlap the second source interconnect part, and
in plan view, the drain pad base at least partially overlaps the first drain interconnect part and does not overlap the second drain interconnect part.

9. The semiconductor device according to claim 7, wherein
the source pad extension is connected to the first source interconnect part and the second source interconnect part by two or more of the source vias, and
the drain pad extension is connected to the first drain interconnect part and the second drain interconnect part by two or more of the drain vias.

10. The semiconductor device according to claim 7, further comprising:
source pads and drain pads alternately arranged in the first direction, wherein
the source pad is one of the source pads, and
the drain pad is one of the drain pads.

11. The semiconductor device according to claim 7, further comprising a multilayer interconnect structure including a first interconnect layer and a second interconnect layer located below the first interconnect layer, wherein
the source pad and the drain pad are arranged in the first interconnect layer,
the source interconnect and the drain interconnect are arranged in the second interconnect layer, and
the source vias and the drain vias are arranged between the first interconnect layer and the second interconnect layer.

12. The semiconductor device according to claim 11, wherein the source interconnect and the drain interconnect are respectively connected to the source electrode and the drain electrode through one or more interconnect layers.

13. The semiconductor device according to claim 1, wherein the transistor is a high-electron-mobility transistor including a nitride semiconductor.

14. The semiconductor device according to claim 1, wherein the transistor is a silicon MOSFET.

15. The semiconductor device according to claim 13, wherein the transistor further includes:
an electron transit layer composed of a nitride semiconductor;
an electron supply layer formed on the electron transit layer and composed of a nitride semiconductor having a band gap that is larger than that of the electron transit layer; and
a gate layer formed on a portion of the electron supply layer and composed of a nitride semiconductor including an acceptor impurity.
